(19) United States
(12) Patent Application Publication
(10) Pub. No.: US 2006/0028804 A1
(43) Pub. Date: Feb. 9, 2006

(54) Ejector, unit and electronic apparatus having the same

(75) Inventor: Hiroshi Hidaka, Kawasaki (JP)

Correspondence Address: STAAS & HALSEY LLP, SUITE 700, 1201 NEW YORK AVENUE, N.W., WASHINGTON, DC, 20005, US

(73) Assignee: Fujitsu Limited, Kawasaki (JP)

(21) Appl. No.: 10/999,317

(22) Filed: Nov. 30, 2004

(30) Foreign Application Priority Data
Aug. 4, 2004 (JP) 2004-227856

(51) Int. Cl. H05K 7/10

(52) U.S. Cl. 361/754

(57) ABSTRACT

An ejector that attaches a unit to and ejects the unit from an electronic apparatus includes a lever that is fixed foldably and unfoldably onto the housing of the unit, a force being applicable to the lever to attach the unit to and eject the unit from the electronic apparatus, and an arm that is elastically deformable and moves between a lock position at which the am is engaged with the lever folded onto the housing of the unit and locks the lever at a folding position, and an unlock position at which the arm unlocks the lever and allows the lever to unfold from the housing of the unit.

This application claims the right of foreign priority under 35 U.S.C. §119 based on Japanese Patent Application No. 2004-227856 filed on Aug. 4, 2004, which is hereby incorporated by reference herein in its entirety as if fully set forth herein.

### BACKGROUND OF THE INVENTION

The present invention relates generally to a unit and an electronic apparatus to which the unit is removably attached, and an ejector mechanism that loads the unit into and ejects the unit from the electronic apparatus. The present invention is suitable, for example, for a disc array storage that removably installs plural hard disc drive (“HDD”) units.

The disc array storage that removably installs one or more HDD units has been recently proposed as a fast, large-capacity and highly reliable external storage (see for example, Japanese Patent Application, Publication No. 2004-54967). The disc array storage allows only a HDD unit that requires maintenance, to be exchanged while keeping a running state of the entire apparatus, and also includes a fixing mechanism that prevents unintentional ejections of the HDD unit(s) from the disc array storage due to vibrations.

FIG. 12 shows a conventional exemplary disc array storage 10 and HDD unit 20 attachable to it. Here, FIG. 12 is a schematic perspective view of the disc array storage 10 and the HDD unit 20. The HDD unit 20 includes, as shown in FIG. 13, a 3.5-inch HDD 30 that has a built-in 3.5-inch disc, and a case 40 that protects the 3.5-inch HDD 30. Here, FIG. 13 is an exploded perspective view of the HDD unit 20.

The 3.5-inch HDD 30 has, as shown in FIGS. 14A and 14B, a width W1, a length L1 and a height H1, which are, for example, 25.4 mm, 147 mm and 101.6 mm, respectively. Here, FIGS. 14A and 14B are front and side views of the 3.5-inch HDD 30.

The case 40 includes, as shown in FIGS. 12 and 13, an ejector mechanism 42 used to insert the 3.5-inch HDD 30 into and eject the 3.5-inch HDD 30 from the disc array storage 10, and a body 44. The ejector mechanism 42 unfolds as shown in FIG. 12 and folds as shown in FIG. 13; the ejector mechanism 42 includes a compression spring (not shown). The ejector mechanism 42 unfolds as shown in FIG. 12, when an eject button (not shown) is pressed to release the engagement by the compression spring while the ejector mechanism 42 is in the state shown in FIG. 13. Thereafter, a user pulls out the HDD unit 20 from the disc array storage 10 by pulling out the ejection mechanism 42. A reverse action is conducted in order to insert the HDD unit 20 into the disc array storage 10.

The case 40 has, as shown in FIGS. 15A and 15B, a width W2, a length L2 and a height H2, which are, for example, 27.1 mm, 204 mm and 112 mm, respectively. Here, FIGS. 15A and 15B are front and side views of the HDD case 40.

Other prior art include Japanese Patent Applications, Publication Nos. 11-260048 and 8-19124.

Recent demands for smaller and lower-profile electronic apparatuses promote studies of an application of a 2.5-inch HDD instead of the 3.5-inch HDD for the next generation of disc array storage 10. In addition, as an amount of available information through the Internet increases, a large-capacity storage is required. Therefore, the disc array storage 10 is requested to install more HDD units 20. Accordingly, the instant inventor has attempted to achieve a smaller HDD unit 20 than the mere application of the 2.5-inch HDD instead of the 3.5-inch HDD. As a result, the instant inventor has discovered that the conventional ejector mechanism 42's length L3, which is about 57 mm, prevents the miniaturization demand.

### BRIEF SUMMARY OF THE INVENTION

Accordingly, it is an exemplary object to provide a smaller ejector that attaches the unit to and ejects the unit from the electronic apparatus, the unit having this ejector, and the electronic apparatus that removably accommodates the unit.

An ejector according to one aspect of the present invention that attaches a unit to and ejects the unit from an electronic apparatus, the unit including a housing, includes a lever that is fixed foldably and unfoldably onto the housing of the unit, a force being applicable to the lever to attach the unit to and eject the unit from the electronic apparatus; and an arm that is elastically deformable and moves between a lock position at which the arm is engaged with the lever folded onto the housing of the unit and locks the lever at a folding position, and an unlock position at which the arm unlocks the lever and allows the lever to unfold from the housing of the unit. In this ejector, the arm is elastically deformable and self-propelled. Therefore, this ejector needs no components, such as a spring, and reduces the number of components, achieving the miniaturization. This arm is made, for example, of resin. This unit is, for example, a storage, such as a HDD unit and other electronic apparatus units. The electronic apparatus is, for example, a disc array storage, and plural electronic apparatuses may be housed in the cascade manner, for example, in a rack mount method.

An ejector according to another aspect of the present invention that attaches a unit to and ejects the unit from an electronic apparatus, the unit including a unit body and a case that covers the unit body, includes a lever that is commonly fixed onto the case of the unit by a fixing member that fixes case onto the unit body, wherein the lever is configured to be foldable and unfoldable around the fixing member relative to the case, a force being applicable to the lever to attach the unit to and eject the unit from the electronic apparatus. According to this ejector, the lever can fold and unfold (or rotate) around the fixing member, such as a screw, and thus the ejector is smaller than the prior art that provides a folding and unfolding mechanism as a separate member.

An ejector according to still another aspect of the present invention that attaches a unit to and ejects the unit from an electronic apparatus, the unit including a unit body and a case that covers the unit body, includes a lever that is fixed foldably and unfoldably onto the case, a force being applicable to the lever to attach the unit to and eject the unit from the electronic apparatus the lever, and an arm that is commonly fixed onto the case by a fixing member that fixes case onto the unit body, the arm moving between a lock position at which the arm is engaged with the lever folded onto the case and locks the lever at a folding position, and an unlock position at which the arm unlocks the lever and allows the lever to unfold from the case of the unit. According to this ejector, the arm can move or displace around the fixing member, such as a screw, and thus the ejector is smaller than the prior art that provides a drive mechanism as a separate member.

An ejector according to another aspect of the present invention that attaches a unit to and ejects the unit from an electronic apparatus, the unit including a unit body and a case that covers the unit body, includes a lever that is commonly fixed onto the case of the unit by a fixing member that fixes case onto the unit body, wherein the lever is configured to be foldable and unfoldable around the fixing member relative to the case, a force being applicable to the lever to attach the unit to and eject the unit from the electronic apparatus, and an arm that is elastically deformable and provided on the surface of the case, on which the lever is fixed, wherein the arm includes a first fixed member that is commonly fixed by the fixing member onto the case, the first fixing member moving between a lock position at which the arm is engaged with the lever folded in the case and locks the lever at a folding position, and an unlock position at which the arm unlocks the lever and allows the lever to unfold from the case of the unit, a second fixed member that is non-movably commonly fixed by the fixing member onto the case, a support member that connects the first and second fixed members to each other, and is so elastically deformable that the support member applies an elastic force to reset to the lock position the first fixed member that moves to the unlock position, an engagement member that is engaged with the lever when the second fixed member is located at the lock position, and disengaged from the lever when the second fixed member is located at the unlock position, and a forcing member that is elastically deformable, and applies a force in a direction to unfold the lever while the forcing member is engaged with the lever. This ejector can exhibit similar operations to the above ejectors.

The lever has, for example, a L-shaped section. When the lever is L-shaped, the lever can be engaged with the unit or the case on its side surface rather than its front surface. As a result, the unit or the case has a simple structure on the front surface, and the length of the unit or the case can be reduced. The L shape enables a user to hold a lever portion that corresponds to the unit's front surface and to apply a force to insert the unit into or eject the unit from the electronic apparatus. It is not preferable that the user holds a lever portion that corresponds to the unit's side surface and applies an unsymmetrical force to the unit through the lever portion.

A direction in which the arm moves from the lock position to the unlock position may be substantially orthogonal to a direction in which the unit is attached to and ejected from the electronic apparatus. The configuration eliminates a necessity to maintain the space for the arm to move in the direction in which the unit is ejected from the electronic apparatus or in the length direction of the unit, and the length of the unit or the case can be reduced. The arm may have a serration to which a force is applied while the arm moves from the lock position to the unlock position. The serration facilitates an engagement between the arm and the user's finger that moves on the arm, and improves the operability. In addition, the serration has a simpler structure than the eject button, and makes the ejector small.

Preferably, the lever may include a tab that is engageable with the electronic apparatus and fixes the unit onto the electronic apparatus when the lever is located at the folding position. This configuration can prevent unintentional ejections or electronic disconnections of the unit from the electronic apparatus due to vibrations, etc. Preferably, the lever includes a connection release member engageable with the electronic apparatus, and releases an electric connection between the unit and the electronic apparatus. The lever's unfolding action serves as an electronic disconnection action between the unit and electronic apparatus, improving the operability.

A unit that includes the above ejector and an electronic apparatus that can removably accommodate the unit also constitute one aspect of the present invention. In particular, the unit may be inserted into and ejected from the electronic apparatus in the height direction of the electronic apparatus. Since the length of the unit should match the height of the electronic apparatus, the reduced length of the unit is effective. When the unit is the HDD unit and the electronic apparatus is the disc array storage of a rack mount type, the height of the conventional disc array storage for the 3.5-inch HDD unit is 3 U (=about 134 mm). Therefore, if the length of the 2.5-inch HDD unit is made within 3 U, the degree of freedom of the loading design increases without greatly changing the design of external size of the disc array storage and the rack mount apparatus that mounts the disc array storages, because the unit can be inserted into the disc array storage in its longitudinal direction or in its height direction.

Other objects and further features of the present invention will become readily apparent from the following description of the preferred embodiments with reference to accompanying drawings.

### BRIEF DESCRIPTION OF THE DRAWINGS

FIG. 1 is a perspective overview of a HDD unit according to one embodiment of the present invention.

FIG. 2 is an exploded perspective view of the HDD unit shown in FIG. 1.

FIGS. 3A and 3B are front and side views of the HDD unit shown in FIG. 2.

FIGS. 4A and 4B are front and side views of a 2.5-inch HDD in the HDD unit shown in FIG. 2.

FIG. 5 is an enlarged sectional view at part A of the HDD unit shown in FIG. 3.

FIG. 6 is an enlarged sectional view at part B of the HDD unit shown in FIG. 3.

FIG. 7 is a sectional view for explaining an ejection of the HDD unit shown in FIG. 1 from the disc array storage.

FIG. 8 is a sectional view for explaining an ejection of the HDD unit shown in FIG. 1 from the disc array storage.

FIG. 9 is a sectional view for explaining an ejection of the HDD unit shown in FIG. 1 from the disc array storage.

FIGS. 10A and 10B are transparent perspective overview and its exploded view that show the way of inserting the HDD unit into and ejecting the HDD unit from the disc array storage in a longitudinal direction.

FIGS. 11A and 11B are transparent perspective overview and its exploded view that show the way of inserting the HDD unit into and ejecting the HDD unit from the disc array storage in a height direction.

FIG. 12 is a schematic perspective view of a conventional disc array storage and HDD unit FIG. 13 is an exploded perspective view of the conventional HDD unit shown in FIG. 12.

FIGS. 14A and 14B are front and side views of a 3.5-inch HDD in the conventional HDD unit shown in FIG. 13.

FIGS. 15A and 15B are front and side views of a case in the conventional HDD unit shown in FIG. 13.

### DETAILED DESCRIPTION OF THE PREFERRED EMBODIMENTS

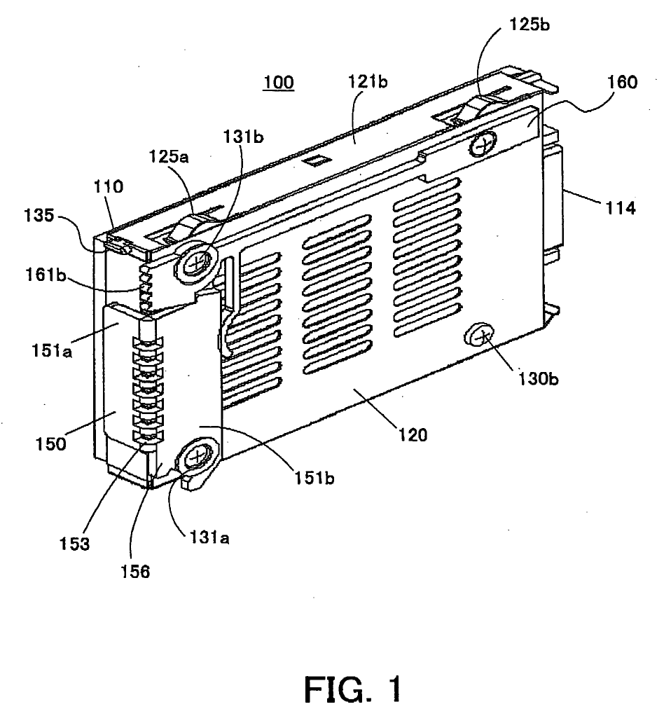

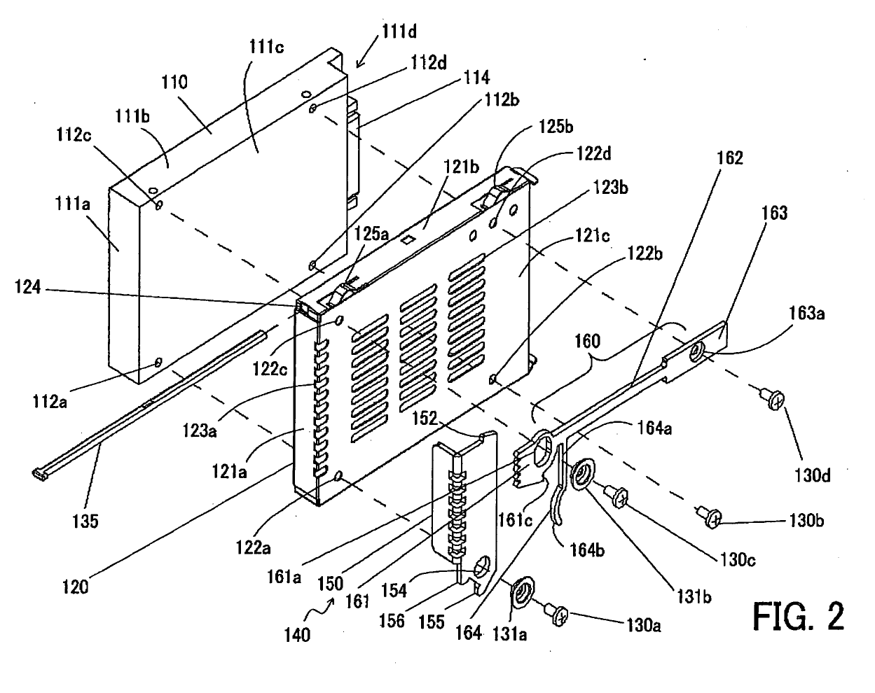

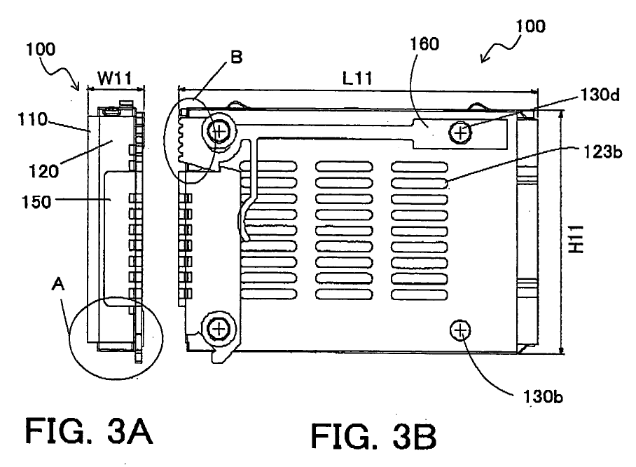

A description will be given of a HDD unit 100 of one embodiment according to the present invention, with reference to the accompanying drawings. Here, FIG. 1 is a perspective overview of the HDD unit 100. FIG. 2 is an exploded perspective view of the HDD unit 199; FIG. 3A is a front view of the HDD unit 100; and FIG. 3B is a side view of the HDD unit 100.

The HDD unit 100 serves as a storage that records and reproduces information, and has, as shown in FIGS. 3A and 3B, a width W11, a length L11 and a height H11, which are, for example, 18 mm, 113.7 mm and 76 mm, respectively. The HDD unit 100 includes, as shown in FIGS. 1 and 2, a 2.5-inch HDD 110, a case or cover 120, fixing members 130a to 130d (which are screws in this embodiment), spacers 131a to 131d, a light guide tube 135, and an ejector mechanism 140.

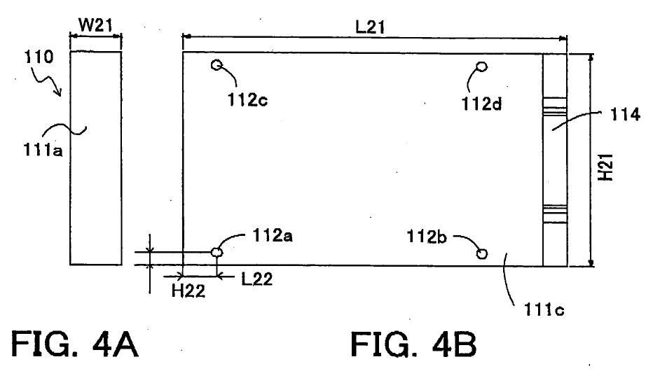

The 2.5-inch HDD 110 is a body of the HDD unit 100, and houses a 2.5-inch magnetic disc. The 2.5-inch HDD 110 possesses, as shown in FIGS. 2, 4A and 4B, a rectangular parallelepiped shape that has a front surface 11a, a top surface 111b, a side surface 111c, and area surface 111d. The 2.5-inch HDD 110 has attachment holes 112a to 112d, and a connector 114. Here, FIG. 4A is a front view of the 2.5-inch HDD 110, and FIG. 4B is a side view of the 2.5-inch HDD 110. The 2.5-inch HDD 110 has, as shown in FIGS. 4A and 4B, a width W21, a length L21 and a height H21, which are, for example, 15 mm, 110.7 mm and 70.1 mm.

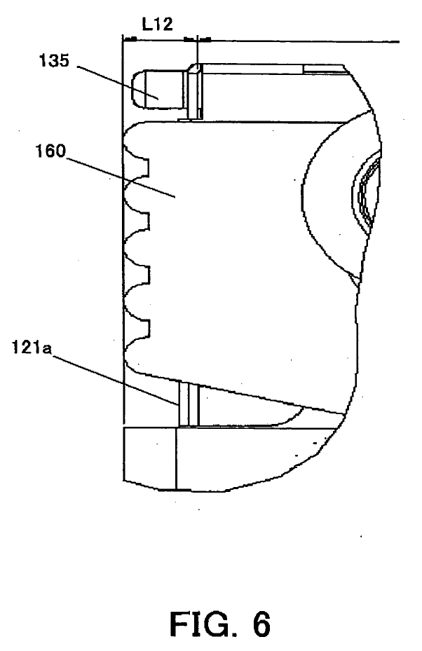

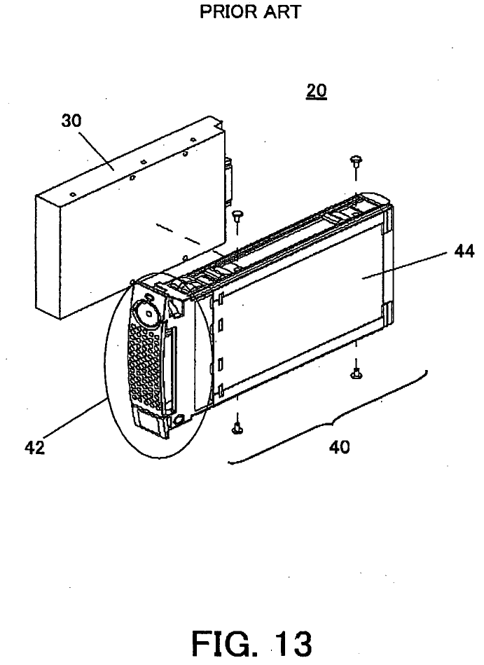

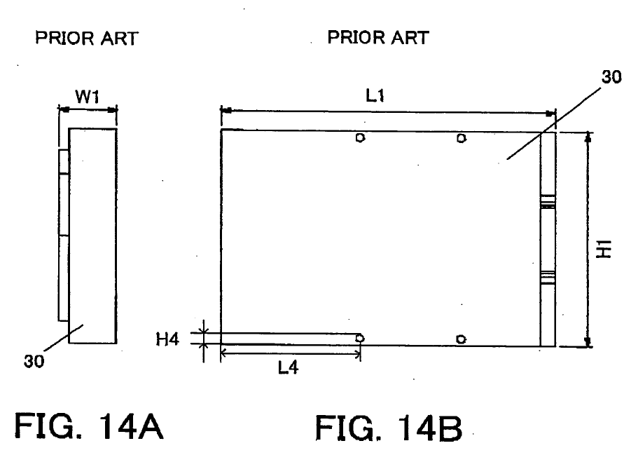

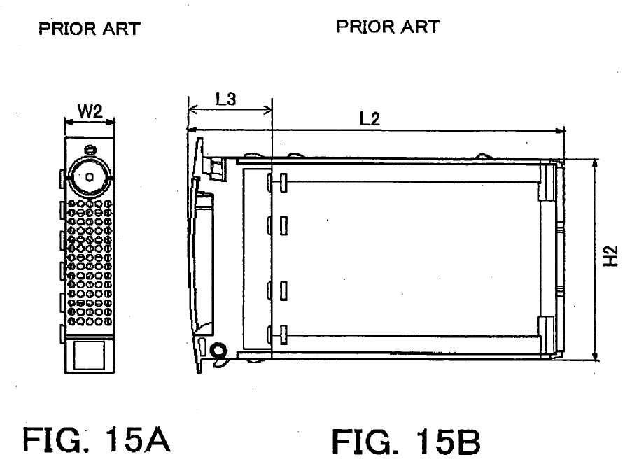

Referring to FIGS. 3, 4A and 4B, a difference between the length L11 of the HDD unit 100 and the length L21 of the 2.5-inch HDD 110 is 113.7−110.7=3 mm. Referring to FIG. 6, a length L12 of the ejector mechanism 140 in the length L11 of the HDD unit 100, by which an arm 160 projects from a front surface 120a of the case 120 is about 3 mm. On the other hand, as shown in FIGS. 14A, 14B, 15A and 15B, a difference between the length L2 of the HDD unit 20 and the length L1 of the 3.5-inch HDD 30 is 204−147=57 mm. In light of the fact that the length L3 of the conventional ejector mechanism 42 is about 57 mm, the HDD unit 100 shortens the length of or miniaturizes the HDD unit 20 by remarkably shortening the length L12 of the ejector mechanism 149 in its length L11. Here, FIG. 6 is an enlarged side view of part B shown in FIG. 3B.

The attachment holes 112a to 112d are provided in the side surface 111c of the 2.5-inch HDD 110, and serve as screw holes, into which screws 130a to 130d are inserted for connections to the case 120. As discussed later, the attachment hole 112a is used to commonly fix the lever 150 of the ejector mechanism 140, and located at a position (length L22, height H22) from the lower left corner, as shown in FIG. 4B. The attachment holes 112c and 112d are used to commonly fix the arm 160 of the ejector mechanism 140.

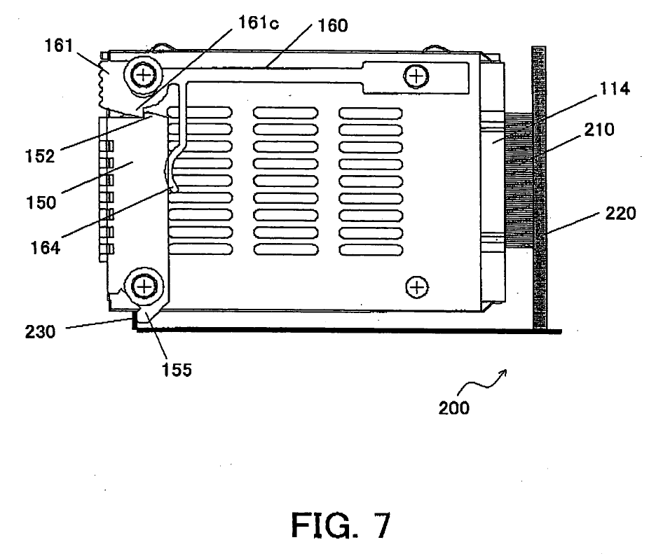

The connector 114 is provided on the rear surface 111d of the 2.5-inch HDD 110, and electrically connected, as shown in FIG. 7, to a connector 210 of a disc array storage 200 for information transmissions and power supplies. The connector 210 is further connected to a back panel 220. Here, FIG. 7 is a sectional view of the HDD unit 100 installed in the disc array storage 200.

The case 120 protects the 2.5-inch HDD 110, and facilitates its insertion into and its ejection from the electronic apparatus 200. The case 120 is formed, for example, by bending a metal plate having a thickness of 0.4 mm. The case 120 has, as shown in FIG. 2, a front surface 121a, a top surface 121b and a side surface 121c. The case 120 opens on surfaces opposing to the front and side surfaces 121a and 121c, and has a tray shape that receives the 2.5-inch HDD 110. As a result, as shown in FIG. 1, the 2.5-inch HDD 110 projects in a width direction of the case 120, and the connector 114 projects from the back of the case 120. The case 120 has attachment holes 122a to 122d, radiation holes 123a and 123b, light guide tube attachment hole 124, and a pair is of vibration absorbers 125a and 125b.

The attachment holes 122a to 122d are provided in the side surface 121c of the case 120. They are screw holes, into which the screws 130a to 130d are inserted for connections with the 2.5-inch HDD 110. As discussed later, the attachment holes 122a is used to commonly fix the lever 150 of the ejector mechanism 140, and the attachment holes 122c and 122d are used to commonly fix the arm 160 of the ejector mechanism 140.

The radiation holes 123a and 123b are perforation holes for radiations of the 2.5-inch HDD 110. The radiation holes 123a are provided at the corner between the front and side surfaces 121a and 121c. The radiation holes 123a are connected, as discussed later, to the radiation holes of the lever 150 of the ejector mechanism 140, and maintain connections between the external air and the 2.5-inch HDD 110. The radiation holes 123b are formed like an exemplary 9×3 matrix in the side surface 121c of the case 120, and maintain the connections between the external air and the 2.5-inch HDD 110.

The light guide tube attachment hole 124 passes under the top surface 121b of the case 120, and serves as a perforation hole, into which the light guide tube 135 is inserted.

The vibration absorbers 125a and 125 contact the top surface 111b of the 2.5-inch HDD 110, and each include a flat spring that absorbs the vibrations applied to the 2.5-inch HDD 110. The vibration absorbers 125a and 125b are provided along a longitudinal direction of the case 120 at the front and back of the top surface 121b of the case 120.

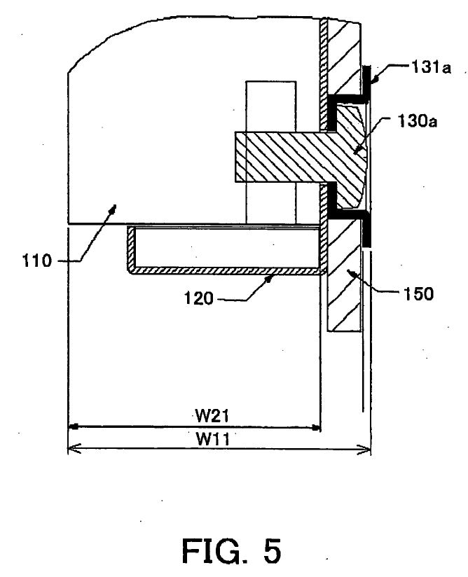

The screws 130a to 130d serve as fixing members that are inserted into the attachment holes 112a to 112d and 122a to 122d, and commonly fix the 2.5-inch HDD 110, the case 120, and the ejector mechanism 140. The screws 130a to 130d are one exemplary fixing member, and the present invention covers any mechanical means, such as a bolt and a nut. The screw 130a is inserted into the above attachment hole via the spacer 131a and the attachment hole 154 of the lever 150 in the ejector mechanism 140. FIG. 5 is an enlarged view of the part A shown in FIG. 3A, The screw 130c is inserted into the above attachment hole via the spacer 131b and an attachment hole 161a of the arm 160 in the ejector mechanism 140. The spacer 131a enables the lever 150 to rotate around the screw 130a. The spacer 131b enables a fixed part 161 of the arm 160 to move relative to the screw 130c.

The light guide tube 135 is an optical fiber to indicate a state of the HDD unit 100, and has an approximately T shape as shown in FIG. 2. The light guide tube 135 is inserted into the attachment hole 124, and projects to the front surface 121a of the case 120, as shown in FIG. 1.

The ejector mechanism 140 enables the HDD unit 100 to be inserted into and ejected from the disc array storage 200, and is provided on the side surface 121C of the case 120. The ejector mechanism 140 locks the engagement between the loaded HDD unit 100 and the disc array storage 200. The ejector mechanism 140 includes the lever 150 and the arm 160.

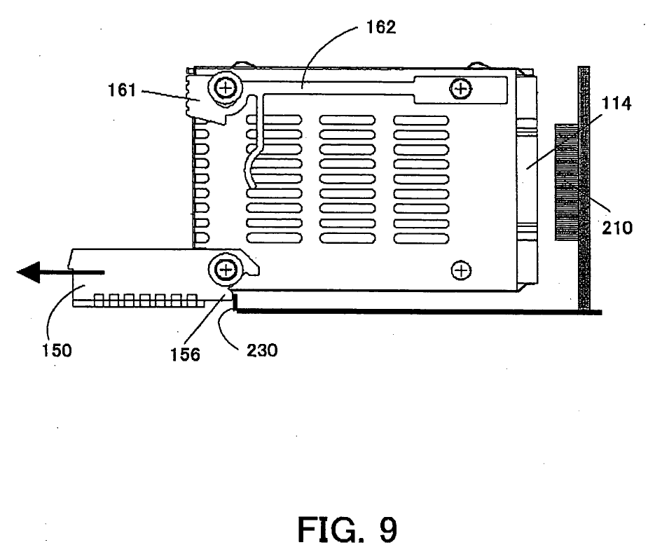

The lever 150 is a member to which a force is applied to insert the HDD unit 100 into and to eject the HDD unit 100 from the disc array storage 200. The lever 150 has an approximately L shape by bending a metal plate having a thickness of 2 mm by a right angle, and is fixed onto the case 120 foldably and unfoldably relative to the case 120. Here, the folding position of the lever 150 is a position shown in FIG. 7, and the unfolding position of the lever 150 is a position shown in FIG. 9, which will be described later. While the instant embodiment allows the lever 150 to rotate by 90° for folding and unfolding, the rotating angle is not limited to 90°. For example, as shown in the ejector mechanism 42 shown in FIG. 13, the lever 150 may be formed like a curve shape.

Since the lever 150 is L-shaped, the lever 150 and the case 120 are engaged with each other via the side and front surfaces 121c and 121a of the case 120, and the folding and unfolding mechanism of the lever 150 can be located on the side surface 121c of the case 120. As a result, the front surface 121a of the case 120 has a simple structure, and the length of the case 120 can be reduced.

The lever 150 includes a front plate 151a and a side plate 151b, which form the L shape, an engagement member 152, radiation holes 153, an attachment hole 154, a tab 155, and a connection release member 156. The radiation holes 153 are provided on the boundary between the front and side plates 151a and 151b, and connected to the radiation holes 123a of the case 120.

The front plate 151a is a member to be held by a user when the lever 150 unfolds, and to which a force is applied at the time of the insertion and ejection. The front plate 151a enables the force to be applied approximately symmetrically with respect to the front surface of the HDD unit 110. The front plate 151a contacts the front surface 121a of the case 120, and prevents the lever 150 from rotating clockwise in FIG. 1. The front plate 151a covers only a center of the front surface 121a of the case, because a serration 161b of the arm, which will be described later, is arranged at the top of the front surface 121a, and if the front plate 151a covers the lower portion of the front surface 121a the front plate 151a would prevent smooth rotations of the lever 150.

The side plate 151b includes the engagement member 152, the attachment hole 154, the tab 155, and the connection release member 156.

The engagement member 152 is a projection provided at the upper right part on the side plate 141b, and engaged with an engagement member 161c of the arm 160 when the lever 150 is located at the folding position as shown in FIG. 7. While the engagement members 152 and 161c extend vertically in the instant embodiment, they may be inclined at predetermined angles or unevenly shaped.

The attachment hole 154 is formed at the bottom center of the side plate 151b, and forms a rotational center of the lever 150. The side plate 151b is fixed onto the side surface 121c of the case 120 rotatable by 90° via the attachment hole 154, the screw 130a and the spacer 131a Since the side plate 151b of the lever 150 can fold and unfold (or rotate) around the screw 130a, the ejector mechanism 140 can be smaller than the prior art that provides the folding and unfolding mechanism as a separate member. The attachment hole 154 is aligned with the attachment hole 112a of the 2.5-inch HDD 110 as described with reference to FIG. 4B, which is formed at almost the corner of the 2.5-inch HDD 110. On the other hand, a lower left position (L4, H4) of the attachment hole 112a shown in FIG. 14B is, for example, (61.27 mm, 3.17 mm), and L4 is so large that the attachment hole is not formed at the corner of the 3.5-inch HDD 30. Therefore, in the conventional 3.5-inch HDD 30, a mere common fixation through the lower left attachment hole shown in FIG. 14B would increase the rotational radius of the ejector mechanism 42 and would not miniaturize the HDD unit 20. The instant embodiment arranges the attachment holes 112a and 122a for the common fixation, at the corner of the HDD unit 100, and reduces the rotational radius of the lever 150, making the ejector mechanism 140 small.

The tab 155 is formed under the attachment hole 154 of the side plate 151b. The tab 155 is engaged with a guide 230 of the disc array storage 200 when the lever is located at the folding position, as shown in FIG. 7, and fixes the HDD unit 100 onto the disc array storage 200. This engagement prevents unintentional ejections of the HDD unit 100 from the disc array storage 200 due to vibrations etc., electronic disconnections between them, and damages of the connectors 114 and 210. While the tab 155 and the guide 230 extend in the vertical direction in the instant embodiment as shown in FIG. 7, they may be inclined at predetermined angles or unevenly shaped.

The connection release member 156 is formed at the left side of the attachment hole 154 of the side plate 151b. The connection release member 156 contacts and presses the guide 230 of the disc array storage 200, as shown in FIG. 9, which will be described later, and disconnects the connector 114 and 210 from each other.

The arm 160 is provided on the side surface 121c of the case 120, made of an elastic material, such as resin, and has an approximately T shape. The arm 160 includes a fixed member 161, a support member 162, a fixed member 163, and a forcing member 164.

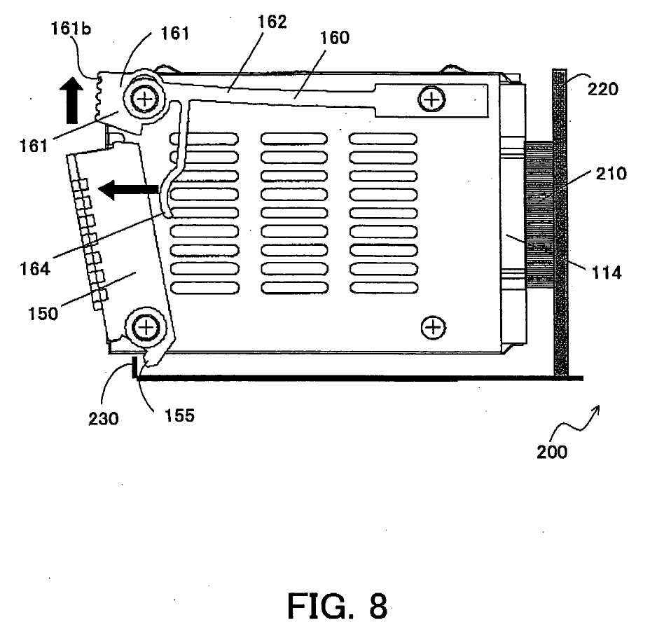

The fixed member 161 is fixed onto the side surface 121c of the case 120 so that it can move between lock and unlock positions. Here, the “lock position” is a position where the fixed member 161 is engaged with the folded lever 150 and locks the lever 150 at the folding position as shown in FIG. 7. The “unlock position” is a position where a lock of the lever 150 is released and the lever 150 is allowed to unfold from the case 120, as shown in FIG. 8. FIG. 8 is a sectional view for explaining an ejecting action of the HDD unit from the disc array storage 200. The fixed member 161 has an attachment hole 161a, a serration 161b, and an engagement member 161c.

The fixed member 161 is fixed onto the side surface 121c of the case 120 with the 2.5-inch HDD 110 via the screw 130c, the spacer 131b, and the attachment hole 161a. The attachment hole 161a has an elliptical shape that is made by extending a circle longitudinally. Therefore, the fixed member 161 can move in the longitudinal direction of the attachment hole 161a or in the upper direction.

The serration 161b is an undulant member formed at the end of the fixed member 161, to which a force is applied when the fixed member 161 is moved from the lock position to the unlock position. The serration 161b facilitates an engagement with the user's finger that moves on the arm 160, improving the operability. In addition, the serration 161b has a simpler and smaller structure than a provision of an eject button etc., and promotes the miniaturization of the ejector mechanism 140. A convex part of the serration 161b is approximately level with the front plate 151a of the folded lever 150. If the serration 161b protrudes, something may be caught by the serration 161b, when the HDD unit 100 is inserted into the disc array storage 200. As a result, the HDD unit 100 may be ejected unintentionally.

The engagement member 161c is a projection that is engaged with the engagement member 152 of the lever 150 when the fixed member 161 is located at the lock position, and releases the engagement with the engagement member 152 of the lever 150 when the fixed member 161 is located at the unlock position. The engagement member 161c protrudes below the attachment hole 161a.

The support member 162 is a rod-shaped member that connects the fixed members 161 and 163 to each other. When the fixed member 161 moves from the lock position to the unlock position, the support member 162 deforms upwardly and generates a reset force for returning to the original state due to its own elastic force. As a result, the fixed member 161 that has moved to the unlock position receives a force to return to the lock position. Since the support member 162 is elastic and self-propelled, no independent reset means, such as a tension spring, is necessary. The reduced number of components contributes to the miniaturization.

The fixed member 163 is fixed non-movably onto the side surface 121c of the case 120 by the screw 130d. Since the fixed member 163 is connected to one end of the support member 162, a structure that does not allow movements of the fixed member 163 when the fixed member 161 moves generates an elastic force to return the fixed member 161 to the lock position. The common fixation enables the arm 160 to move or displace around the fixed member 163 or the screw 130d, and no independent drive means is necessary unlike the prior art, making the ejector mechanism smaller.

The forcing member 164 applies a force to the top of the side plate 151b in the unfolding direction of the lever 150, as shown in FIG. 7, when the engagement members 161c and 152 are engaged with each other. The forcing member 164 extends downwardly from the support member 161 near the fixed member 161, and includes a vertical portion 164a and a curved portion 164b. The vertical portion 164a is connected to the support member 162 and extends downwardly approximately perpendicular to the support member 162. The curved portion 164b is connected to the vertical portion 164a, and contacts the side plate 151b. A combination of the vertical portion 164a and the curved portion 164b can make the forcing member 164 as small as possible, and allows the forcing member 164 to be located near the lever 150. The curved portion 164 is elastically deformable and applies an elastic force to the side plate 151b. Since the forcing member 164 is elastically deformable and self-propelled, no independent forcing means, such as a compression spring, is necessary. The reduced number of components contributes to the miniaturization of the ejector mechanism 140.

Referring now to FIGS. 7 to 9, a description will be given of the ejection of the HDD unit 100 from the disc array storage 200. Here, FIG. 9 is a sectional view for explaining the ejection action of the HDD unit from the disc array storage 200, following the state shown in FIG. 8. In order to insert the HDD unit 100 into the disc array storage 200, the reverse action to the following description will be conducted.

First, when the fixed member 161 is located at the lock position shown in FIG. 7, the engagement members 152 and 161c are engaged with each other and the lever 150 is locked to the folding state. The tab 155 is engaged with the guide 230, preventing the HDD unit 100 from being unintentionally ejected from the disc array storage 200 due to the vibrations, etc. In addition, the connectors 114 and 230 are connected to each other, and the HDD unit 100 and the disc array storage 200 are electrically connected to each other. The HDD unit 100 is supplied with power, and records and reproduces information. The forcing member 164 applies a compression force to the lever 150.

Next, a user engages his finger with the serration 161b, lifts up the fixed member 161 in the arrow direction in FIG. 8, and moves the fixed member 161 along the attachment hole 161a to the unlock position. A direction in which the fixed member 161 moves from the lock position to the unlock position is substantially orthogonal to a direction in which the HDD unit 100 is ejected from the disc array storage 200 (or the arrow direction in FIG. 9). The phrase “substantially orthogonal” intends to cover a not completely orthogonal case because the fixed member 161 rotates around the screw 130d. Anyway, the configuration that makes the moving directions orthogonal eliminates a necessity to maintain the space for the arm 160 to move in the direction in which the HDD unit 100 is ejected from the disc array storage 200 or in the length direction of the HDD unit. Therefore, this configuration makes the HDD unit 100 or the case 120 shorter.

In the state shown in FIG. 8, the engagement members 152 and 161c are disengaged from each other, and the lever 150 is unlocked from the folding state. The tab 155 is disengaged from the guide 230, and the HDD unit 100 can be ejected from the disc array storage 200. However, the engagement between the connectors 114 and 210 is still maintained in this state, and the HDD unit 100 is held in the disc array storage 200. Moreover, the elastic force by the forcing member 164 inclines the lever 150 in the front arrow direction, and the user easily rotates the lever 150 to the front. As a result, the forcing member 164 is spaced from the lever 150. The support member 162 generates a force to return to the state shown in FIG. 7.

Next, the user separates his finger from the serration 161b. Then, the reset force applied to the support member 162 resets the fixed member 161 to the state shown in FIG. 7. While the lever 150 is moving to the unfolding position shown in FIG. 9, the connection release member 156 contacts the guide 230 of the disc array storage 200. When the user rotates the lever 150 to the unfolding position so that the rotational angle becomes 90°, the connection release member 156 presses the guide 230 and disconnects the connectors 114 and 210 from each other consequently. Since the lever's unfolding action serves to release the electric connection between the HDD unit 100 and the disc array storage 200, the operability improves. Thereby, no force holds the HDD unit 110 in the disc array storage 200, and the user can eject the HDD unit 100 from the disc array storage 200 by holding and pulling out the front plate 151a of the lever 150 in the front arrow direction.

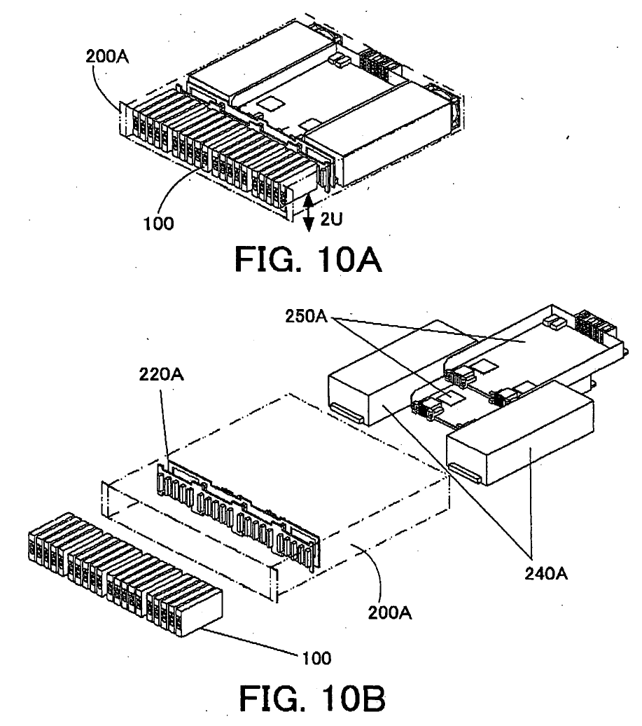

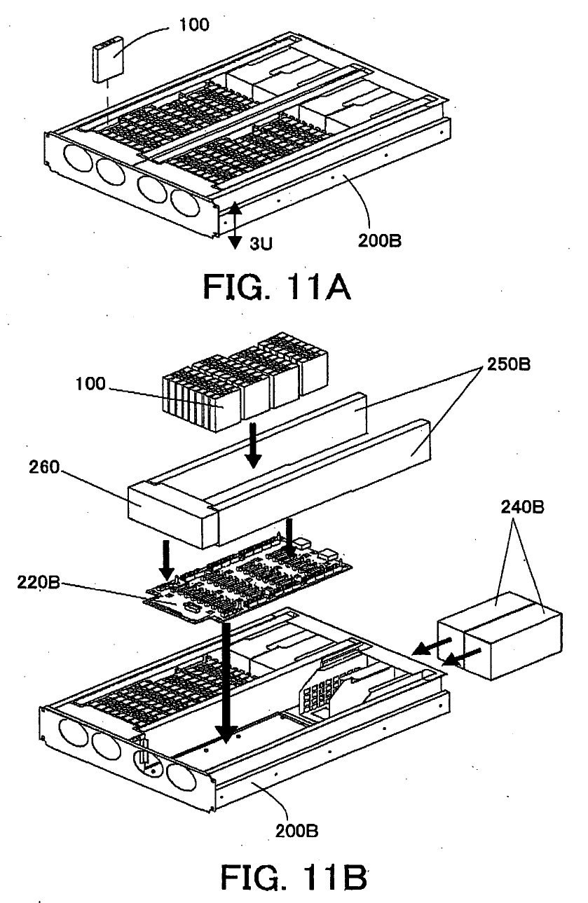

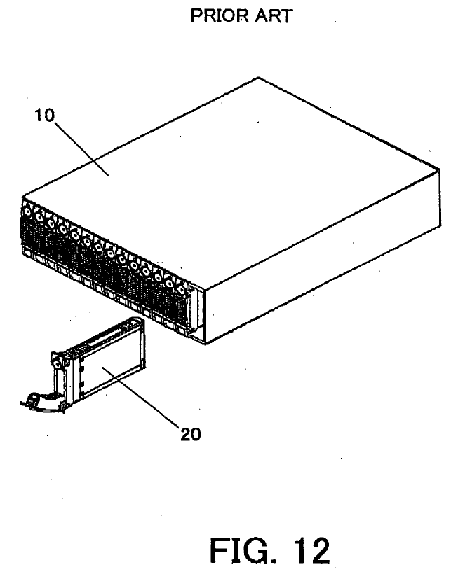

Referring now to FIGS. 10A, 10B, 11A and 11B, a description will be given of the exemplary loading methods of the HDD unit 100 into the disc array storage 200. The disc array storage 200 is a big computer that serves as an auxiliary storage used mainly for data backup.

FIGS. 10A and 10B show the way of inserting the HDD unit 100 into and ejecting the HDD unit 100 from the disc array storage 200A in the longitudinal direction of the disc array storage 200A. FIG. 10A is a transparent perspective overview of the disc array storage 200A into which twenty HDD disc units 100 are loaded. FIG. 10B is an exploded view of FIG. 10A. 220A is a back panel, 240A is a power unit, and 250A is an interface unit. The disc array storage 200A has the height of 2 U (=88.9 mm), for example.

On the other hand, FIGS. 11A and 11B show the inserting the HDD unit 100 into and ejecting the HDD unit 100 from the disc array storage 200B in the height direction of the disc array storage 200B. FIG. 11A is a transparent perspective overview of the disc array storage 200B into which sixty HDD disc units 100 are loaded. FIG. 11B is an exploded view of FIG. 11A. 220B is a back panels 240B is a power unit, 250B is an interface unit, and 260 is a cooling fan unit. The disc array storage 200B has the height of 3 U (=133.35 mm), for example Since the length of the HDD unit 100 should match the height of the disc array storage 200B in FIG. 11, the reduced length of the HDD unit 100 is effective. The height of the disc array storage for 2.5-inch HDD unit is 3 U. If the length of the 2.5-inch HDD unit is made within 3 U, the degree of freedom of the loading design increases without greatly changing the design of external shapes of the disc array storage 200B and the rack mount apparatus that mounts the disc array storages 200B, because the HDD unit 100 can be inserted into the disc array storage 200B in its longitudinal direction as shown in FIG. 10 or in its height direction as shown in FIG. 11.

Further, the present invention is not limited to these preferred embodiments, and various variations and modifications may be made without departing from the scope of the present invention. For example, the above embodiment discusses the unit as the HDD unit and the electronic apparatus as the disc array storage, but the unit is applicable to a network unit and a disc drive in addition to the HDD and the electronic apparatus may be a rack-mount housing unit.

Thus, the present invention can provide a smaller ejector that attaches the unit to and ejects the unit from the electronic apparatus, the unit having this ejector, and the electronic apparatus that removably accommodates the unit.

What is claimed is:

1. An ejector that attaches a unit to and ejects the unit from an electronic apparatus, said unit including a housing, said ejector comprising:
a lever that is fixed foldably and unfoldably onto the housing of the unit, a force being applicable to said lever to attach the unit to and eject the unit from the electronic apparatus; and
an arm that is elastically deformable and moves between a lock position at which said arm is engaged with said lever folded onto the housing of the unit and locks said lever at a folding position, and an unlock position at which said arm unlocks said lever and allows said lever to unfold from the housing of the unit.

2. An ejector according to claim 1, wherein said lever has a L-shaped section.

3. An ejector according to claim 1, wherein a direction in which said arm moves from the lock position to the unlock position is substantially orthogonal to a direction in which the unit is attached to and ejected from the electronic apparatus.

4. An ejector according to claim 1, wherein said arm has a serration to which a force is applied while said arm moves from the lock position to the unlock position.

5. An ejector according to claim 1, wherein said lever includes a tab that is engageable with the electronic apparatus and fixes said unit onto the electronic apparatus when said lever is located at the folding position.

6. An ejector according to claim 1, wherein said lever includes a connection release member engageable with the electronic apparatus, and releases an electric connection between the unit and the electronic apparatus.

7. An ejector that attaches a unit to and ejects the unit from an electronic apparatus, said unit including a unit body and a case that covers the unit body, said ejector comprising:
a lever that is commonly fixed onto the case of the unit by a fixing member that fixes case onto the unit body, wherein said lever is configured to be foldable and unfoldable around the fixing member relative to the case, a force being applicable to said lever to attach the unit to and eject the unit from the electronic apparatus.

8. An ejector that attaches a unit to and ejects the unit from an electronic apparatus, said unit including a unit body and a case that covers the unit body, said ejector comprising:
a lever that is fixed foldably and unfoldably onto the case, a force being applicable to said lever to attach the unit to and eject the unit from the electronic apparatus said lever; and
an arm that is commonly fixed onto the case by a fixing member that fixes case onto the unit body, said arm moving between a lock position at which said arm is engaged with said lever folded onto the case and locks said lever at a folding position, and an unlock position at which said arm unlocks said lever and allows said lever to unfold from the case of the unit.

9. An ejector that attaches a unit to and ejects the unit from an electronic apparatus, said unit including a unit body and a case that covers the unit body, said ejector comprising:
a lever that is commonly fixed onto the case of the unit by a fixing member that fixes case onto the unit body, wherein said lever is configured to be foldable and unfoldable around the fixing member relative to the case, a force being applicable to said lever to attach the unit to and eject the unit from the electronic apparatus; and
an arm that is elastically deformable and provided on the surface of the case, on which the lever is fixed,
wherein said am includes:
a first fixed member that is commonly fixed by the fixing member onto the case, said first fixing member moving between a lock position at which said arm is engaged with said lever folded in the case and locks said lever at a folding position, and an unlock position at which said arm unlocks said lever and allows said lever to unfold from the case of the unit;
a second fixed member that is non-movably commonly fixed by the fixing member onto the case;
a support member that connects the first and second fixed members to each other, and is so elastically deformable that said support member applies an elastic force to reset to the lock position the first fixed member that moves to the unlock position;
an engagement member that is engaged with said lever when the second fixed member is located at the lock position, and disengaged from the lever when the second fixed member is located at the unlock position; and
a forcing member that is elastically deformable, and applies a force in a direction to unfold said lever while the forcing member is engaged with said lever.

10. A unit that comprising an ejector that attaches a unit to and ejects the unit from an electronic apparatus, said unit including a housing,
wherein said ejector includes:
a lever that is fixed foldably and unfoldably onto the housing of the unit, a force being applicable to said lever to attach the unit to and eject the unit from the electronic apparatus; and
an arm that is elastically deformable and moves between a lock position at which said arm is engaged with said lever folded onto the housing of the unit and locks said lever at a folding position, and an unlock position at which said arm unlocks said lever and allows said lever to unfold from the housing of the unit.

11. An electronic apparatus that removably accommodates a unit that includes an ejector that attaches a unit to and ejects the unit from an electronic apparatus, said unit including a housing,
wherein said ejector includes:
a lever that is fixed foldably and unfoldably onto the housing of the unit, a force being applicable to said lever to attach the unit to and eject the unit from the electronic apparatus; and
an arm that is elastically deformable and moves between a lock position at which said arm is engaged with said lever folded onto the housing of the unit and locks said lever at a folding position, and an unlock position at which said arm unlocks said lever and allows said lever to unfold from the housing of the unit.
